(19) United States
(12) Patent Application Publication
(10) Pub. No.: US 2025/0359470 A1
(43) Pub. Date: Nov. 20, 2025

(54) DISPLAY DEVICE

(71) Applicant: SAMSUNG DISPLAY CO., LTD., YONGIN-SI (KR)

(72) Inventors: Seong Yong HWANG, Yongin-si (KR); Yeong Ho LEE, Yongin-si (KR); Jin Su LEE, Yongin-si (KR); Choong Youl IM, Yongin-si (KR); Seong Min CHO, Yongin-si (KR)

(21) Appl. No.: 19/042,048

(22) Filed: Jan. 31, 2025

(30) Foreign Application Priority Data
May 16, 2024 (KR) 10-2024-0063751

(51) Int. Cl. H10K 59/80; G06F 3/041; G06F 3/044; H10K 59/40

(52) U.S. Cl. CPC H10K 59/879; G06F 3/0412; G06F 3/0446; H10K 59/40; H10K 59/873

(57) ABSTRACT

A display device comprises a display panel including a display area having pixels, and a touch sensing unit disposed on a front surface of the display panel and sensing a user's touch. The touch sensing unit comprises a first touch insulating layer on an encapsulation layer in the display area, a second touch insulating layer on the first touch insulating layer, touch electrodes on the second touch insulating layer, a third touch insulating layer on the touch electrodes and the second touch insulating layer, a color filter layer on the third touch insulating layer and overlapping with the pixels, and at least one cover window on the color filter layer and the display panel. The third touch insulating layer is composed of an insulating material having a refractive index ranging between a refractive index of the second touch insulating layer and a refractive index of the color filter layer.

This application claims priority under 35 U.S.C. 119 to Korean Patent Application No. 10-2024-0063751, filed on May 16, 2024 in the Korean Intellectual Property Office, the present disclosure of which is incorporated by reference in its entirety herein.

### 1. TECHNICAL FIELD

The present disclosure relates to a display device and an electronic device.

### 2. DISCUSSION OF RELATED ART

There has been an increased demand for display devices applied to various different electronic devices along with the advancement of the information society. For example, display devices are being applied to a variety of different electronic devices such as smart phones, digital cameras, laptop computers, navigation devices, and smart televisions.

Display devices may be flat panel display devices such as a liquid-crystal display device, a field emission display device, and an organic light-emitting display device. Among these display devices, a light-emitting display device, in which each of the pixels of the display panel includes a light-emitting element that is self emissive, can display images without a backlight unit supplying light to the display panel.

Recently, a display device has been developed that includes a touch detection module for sensing a user's touch as a user input interface. A touch sensing module includes a touch sensing unit in which touch electrodes are arranged, and a touch driver circuit that detects the amount of charges stored in the capacitance between the touch electrodes. The touch sensing unit may be mounted on an image display area of a display device or may be formed integrally with the image display area. A slimmer display device can be implemented when the touch sensing unit is formed integrally with the image display area.

### SUMMARY

Aspects of the present disclosure provide a display device that enhances the thicknesses and materials of touch insulating layers of a touch sensor unit that is formed integrally with an image display area in a display device, to prevent distortion of the reflectance in the front direction due to differences in the refractive indexes of the color filters.

Aspects of the present disclosure also provide a display device that can lower the light reflectance of touch insulating layers by enhancing the refractive indexes of the touch insulating layers to increase destructive interference of lights reflected by the touch insulating layers.

It should be noted that objects of embodiments of the present disclosure are not limited to the above-mentioned object; and other objects of embodiments of the present disclosure will be apparent to those skilled in the art from the following descriptions.

According to an embodiment of the present disclosure, a display device includes a display panel comprising a display area including a plurality of pixels disposed therein. A touch sensing unit is disposed on a front surface of the display panel. The touch sensing unit senses a user's touch. The touch sensing unit comprises a first touch insulating layer disposed on a front surface of an encapsulation layer formed in the display area. A second touch insulating layer is disposed on a front surface of the first touch insulating layer. A plurality of touch electrodes is patterned on the second touch insulating layer. A third touch insulating layer is disposed on the plurality of touch electrodes and a front surface of the second touch insulating layer. A color filter layer is disposed on the third touch insulating layer and overlaps the pixels in the display area. At least one cover window is disposed on the color filter layer and the front surface of the display panel. The third touch insulating layer is composed of an insulating material having a refractive index ranging between a refractive index of the second touch insulating layer and a refractive index of the color filter layer.

According to an embodiment of the present disclosure, a display device includes a display panel comprising a display area including a plurality of pixels disposed therein. An encapsulation layer is arranged to cover a front surface of the display area. A first touch insulating layer is disposed on a front surface of the encapsulation layer. A second touch insulating layer is disposed on a front surface of the first touch insulating layer. A plurality of touch electrodes is patterned on the second touch insulating layer. A third touch insulating layer is disposed on the plurality of touch electrodes and a front surface of the second touch insulating layer. A color filter layer is disposed on the third touch insulating layer and overlaps with the pixels in the display area. At least one cover window is disposed on the color filter layer and a front surface of the display panel. The third touch insulating layer has a refractive index that is less than a refractive index of the second touch insulating layer and greater than a refractive index of the color filter layer.

According to an embodiment of the present disclosure, an electronic device comprising a processor, a memory connected to the processor, and a display device connected to the processor, wherein the display device comprising a display panel comprising a display area including a plurality of pixels disposed therein, and a touch sensing unit disposed on a front surface of the display panel, the touch sensing unit sensing a user's touch, wherein the touch sensing unit comprises a first touch insulating layer disposed on a front surface of an encapsulation layer formed in the display area, a second touch insulating layer disposed on a front surface of the first touch insulating layer, a plurality of touch electrodes patterned on the second touch insulating layer, a third touch insulating layer disposed on the plurality of touch electrodes and a front surface of the second touch insulating layer, a color filter layer disposed on the third touch insulating layer and overlapping the plurality of pixels in the display area, and at least one cover window disposed on the color filter layer and the front surface of the display panel, and wherein the third touch insulating layer is composed of an insulating material having a refractive index ranging between a refractive index of the second touch insulating layer and a refractive index of the color filter layer.

According to embodiments of the present disclosure, a display device can prevent distortion of the reflectance in the front direction due to differences in the refractive indexes of the color filter, thereby preventing deterioration of the display quality and increasing user satisfaction.

In addition, according to an embodiment of the present disclosure, a display device can lower the light reflectance of touch insulating layers by enhancing the refractive indexes of the touch insulating layers to increase the display quality and increase user reliability.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a perspective view of a display device according to an embodiment of the present disclosure.

FIG. 2 is a plan view showing a display device according to an embodiment of the present disclosure.

FIG. 3 is a view showing a side of the display device according to an embodiment of the present disclosure.

FIG. 4 is a view showing a layout of the display panel shown in FIGS. 1 to 3 according to an embodiment of the present disclosure.

FIG. 5 is a view showing a layout of the touch sensing module shown in FIG. 3 according to an embodiment of the present disclosure.

FIG. 6 is an enlarged, plan view showing in detail the touch nodes shown in FIG. 5 according to an embodiment of the present disclosure.

FIG. 7 is a cross-sectional view showing the display panel taken along line I-I′ of FIG. 5 according to an embodiment of the present disclosure.

FIG. 8 is a cross-sectional view showing the cross-sectional structure taken along line I-I of FIG. 7 as simple blocks according to an embodiment of the present disclosure.

FIG. 9 is a graph showing the effects of reducing light reflectance by improving the materials and layer thicknesses of the touch insulating layers according to an embodiment of the present disclosure.

FIG. 10 is a block diagram of an electronic device according to one embodiment.

FIGS. 11, 12 and 13 are schematic diagrams of electronic devices according to various embodiments.

### DETAILED DESCRIPTION OF EMBODIMENTS

The present disclosure will now be described more fully hereinafter with reference to the accompanying drawings, in which non-limiting embodiments of the present disclosure are shown. The present disclosure may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

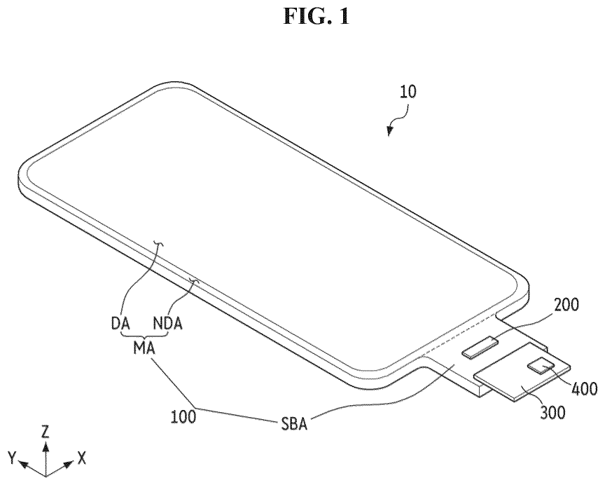

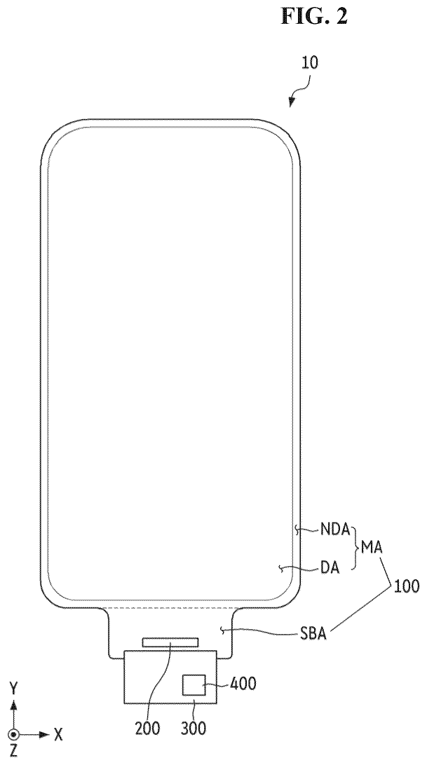

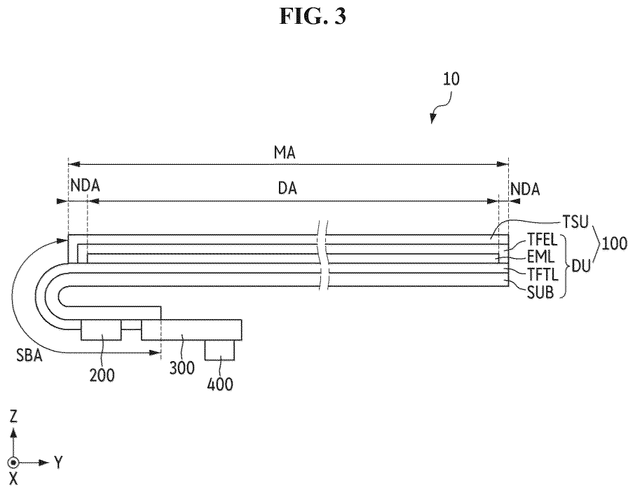

FIG. 1 is a perspective view showing a display device according to an embodiment of the present disclosure. FIG. 2 is a plan view showing the display device according to an embodiment of the present disclosure. FIG. 3 is a view showing a side of the display device according to an embodiment of the present disclosure.

Referring to FIGS. 1 to 3, a display device 10 according to an embodiment of the present disclosure may be applied to portable electronic devices such as a mobile phone, a smart phone, a tablet PC, a mobile communications terminal, an electronic notebook, an electronic book, a portable multimedia player (PMP), a navigation device and a ultra mobile PC (UMPC). In addition, the display device 10 according to an embodiment of the present disclosure may be used as a display unit of a television, a laptop computer, a monitor, an electronic billboard, or the Internet of Things (IOT). In addition, the display device 10 according to an embodiment of the present disclosure may be applied to wearable devices such as a smart watch, a watch phone, a glasses-type display, and a head-mounted display (HMD) device. In addition, the display device 10 according to an embodiment may be used as a center information display (CID) disposed at the instrument cluster, the center fascia or the dashboard of a vehicle, as a room mirror display on the behalf of the side mirrors of a vehicle, as a display placed on the back of each of the front seats that is an entertainment system for passengers at the rear seats of a vehicle. However, embodiments of the present disclosure are not necessarily limited thereto.

According to an embodiment of the present disclosure, the display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (e.g., micro LEDs or nano LEDs). In the following description, an organic light-emitting display device is described as an example of the display device 10 according to an embodiment. It is, however, to be understood that embodiments of the present disclosure are not necessarily limited thereto.

According to an embodiment of the present disclosure, the display device 10 includes a display panel 100 with a touch sensing unit TSU, a display driver circuit 200, a display circuit board 300, and a touch driver circuit 400.

In an embodiment, the display panel 100 may be formed in a rectangular plane having shorter sides in a first direction (e.g., the x-axis direction) and longer sides in a second direction (e.g., the y-axis direction) intersecting the first direction (e.g., the x-axis direction). Each of the corners where the shorter sides in the first direction (x-axis direction) meet the longer sides in the second direction (y-axis direction) may be rounded with a predetermined curvature or may be a right angle. However, the shape of the display panel 100 when viewed from the top is not necessarily limited to a quadrangular shape, but may be formed in a different polygonal shape, a circular shape, or an elliptical shape. In an embodiment, the display panel 100 may be formed flat. However, embodiments of the present disclosure are not necessarily limited thereto. For example, the display panel 100 includes curved portions formed at left and right ends and having a constant curvature or a varying curvature. In addition, the display panel 100 may be formed to be flexible so that it can be curved, bent, folded or rolled.

The display panel 100 includes a main area MA and a subsidiary area SBA.

The main area MA includes a display area DA where images are displayed, and a non-display area NDA around the display area DA (e.g., in a plan view). The display area DA includes pixels for displaying images. In an embodiment, the subsidiary area SBA may protrude from one side of the main area MA in the second direction (e.g., the y-axis direction). For example, the subsidiary area SBA may protrude from a lower side of the main area MA in the second direction (e.g., the y-axis direction).

Although the subsidiary area SBA is unfolded in the example shown in FIGS. 1 and 2, the subsidiary area SBA may be bent as shown in FIG. 3 and may be disposed on the lower surface of the display panel 100. When the subsidiary area SBA is bent, it may overlap with the main area MA in the third direction (e.g., the z-axis direction), which is the thickness direction of the substrate SUB. The display driver circuit 200 may be disposed in the subsidiary area SBA.

As shown in FIG. 3, in an embodiment the display panel 100 includes a display module DU including the substrate SUB, a thin-film transistor layer TFTL, an emission material layer EML and an encapsulation layer TFEL, and a touch sensing unit TSU formed on the front surface of the display module DU.

The thin-film transistor layer TFTL may be disposed on the substrate SUB. The thin-film transistor layer TFTL may be disposed in the main area MA and the subsidiary area SBA. The thin-film transistor layer TFTL includes thin-film transistors.

The emission material layer EML may be disposed on the thin-film transistor layer TFTL. The emission material layer EML may be disposed in the display area DA of the main area MA. The emission material layer EML includes light-emitting elements disposed in emission areas.

The encapsulation layer TFEL may be formed on the emission material layer EML (e.g., formed directly thereon in the z-axis direction). The encapsulation layer TFEL may be formed in the display area DA and the non-display area NDA of the main area MA. The encapsulation layer TFEL includes at least one inorganic layer and at least one organic layer for encapsulating the emission material layer.

The touch sensing unit TSU may be formed on the encapsulation layer TFEL or mounted on the encapsulation layer TFEL. In an embodiment, the touch sensing unit TSU may be formed on the display area DA of the main area MA. The touch sensing unit TSU may sense a touch of a person or an object using sensor electrodes.

At least one cover window for protecting the display panel 100 from above may be disposed on the touch sensing unit TSU. In an embodiment, at least one cover window may be attached on the touch sensing unit TSU by a transparent adhesive member such as an optically clear adhesive (OCA) film and an optically clear resin (OCR). The cover window may be an inorganic material such as glass, or an organic material such as plastic and polymer material. In an embodiment, a polarizing layer may be further disposed between the touch sensing unit TSU and the cover window (e.g., in the z-axis direction) to prevent deterioration of image visibility due to reflection of external light.

The display driver circuit 200 may generate signals and voltages for driving the display panel 100. In an embodiment, the display driver circuit 200 may be implemented as an integrated circuit (IC) and may be attached to the display panel 10 by a chip on glass (COG) technique, a chip on plastic (COP) technique, or an ultrasonic bonding. However, embodiments of the present disclosure are not necessarily limited thereto. For example, in an embodiment the display driver circuit 200 may be attached on the display circuit board 300 by the chip-on-film (COF) technique.

The display circuit board 300 may be attached to one end of the subsidiary area SBA of the display panel 100. The display panel 100 and the display driver circuit 200 may receive digital video data, timing signals, and driving voltages from an external graphic system or the like through the display circuit board 300. In an embodiment, the display circuit board 300 may be a flexible printed circuit board, a printed circuit board, or a flexible film such as a chip-on film.

The touch driver circuit 400 may be disposed on (e.g., disposed directly thereon) the display circuit board 300. In an embodiment, the touch driver circuit 400 may be implemented as an integrated circuit (IC) and may be mounted on the display circuit board 300.

The touch driver circuit 400 may be electrically connected to the touch electrodes of the touch sensing unit TSU. In an embodiment, the touch driver circuit 400 applies touch driving signals to the touch electrodes of the touch sensing unit TSU, and measures the amount of change in the mutual capacitance of touch nodes formed by the touch electrodes. For example, in an embodiment the touch driver circuit 400 applies touch driving signals to the touch electrodes and measures a change in capacitance of the touch nodes according to a change in the level of voltage or the amount of current of a touch sensing signal received through the touch electrodes. In this manner, the touch driver circuit 400 may determine whether there is a user's touch or near proximity, based on the amount of a change in the mutual capacitance of each of the touch nodes. A user's touch refers to that an object such as the user's finger or an electronic pen is brought into direct contact with a surface of the cover window disposed on the touch sensing unit TSU. A user's near proximity refers to that an object such as the user's finger and an electronic pen is hovering over a surface of the cover window and is not in direct contact with a surface of the cover window.

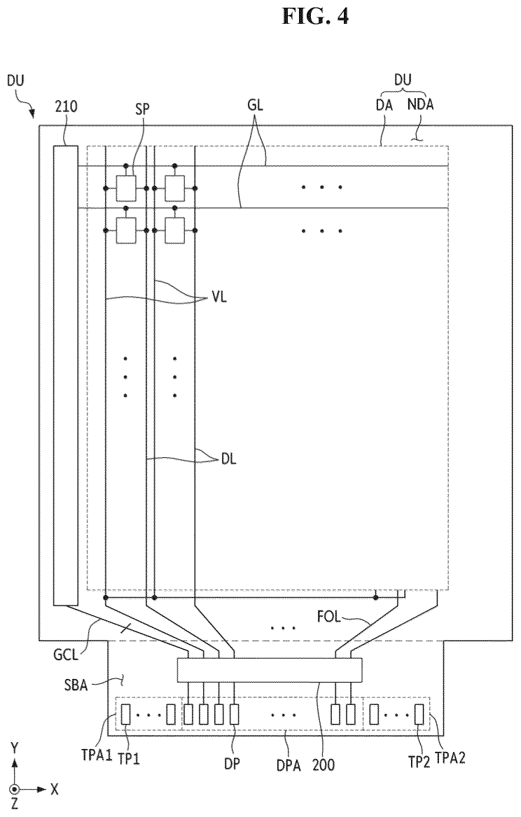

FIG. 4 is a view showing an example of a layout of the display panel shown in FIGS. 1 to 3. Specifically, FIG. 4 is a layout view showing the display area DA and the non-display area NDA of the display module DU before the touch sensing unit TSU is formed.

The display area DA displays images therein and may be defined as a central area of the display panel 100 (e.g., in a plan view). In an embodiment, the display area DA may include a plurality of pixels SP, a plurality of gate lines GL, a plurality of data lines DL and a plurality of voltage lines VL. Each of the plurality of pixels SP may be defined as the minimum unit that outputs light.

The plurality of gate lines GL may supply the gate signals received from the gate driver 210 to the plurality of pixels SP. In an embodiment, the plurality of gate lines GL may extend longitudinally in the x-axis direction and may be spaced apart from one another in the y-axis direction crossing the x-axis direction.

The plurality of data lines DL may provide the data voltages received from the display driver circuit 200 to the plurality of pixels SP. In an embodiment, the plurality of data lines DL may extend longitudinally in the y-axis direction and may be spaced apart from one another in the x-axis direction.

The plurality of voltage lines VL may supply the supply voltage received from the display driver circuit 200 to the plurality of pixels SP. In an embodiment, the supply voltage may be at least one of a driving voltage, an initialization voltage, and a reference voltage. In an embodiment, the plurality of voltage lines VL may extend longitudinally in the y-axis direction and may be spaced apart from one another in the x-axis direction.

The non-display area NDA may surround the display area DA (e.g., in a plan view). In an embodiment, the non-display area NDA may include the gate driver 210, fan-out lines FOL, and gate control lines GCL. In an embodiment, the gate driver 210 may generate a plurality of gate signals based on the gate control signal, and may sequentially supply the plurality of gate signals to the plurality of gate lines GL in a predetermined order.

The fan-out lines FOL may extend from the display driver circuit 200 to the display area DA. The fan-out lines FOL may supply the data voltage received from the display driver circuit 200 to the plurality of data lines DL.

The gate control line GCL may extend from the display driver circuit 200 to the gate driver 210. The gate control line GCL may supply the gate control signal received from the display driver circuit 200 to the gate driver 210.

In an embodiment, the subsidiary area SBA may include the display driver circuit 200, a display pad area DPA, and first and second touch pad areas TPA1 and TPA2.

In an embodiment, the display driver circuit 200 may output signals and voltages for driving the display panel 100 to the fan-out lines FOL. The display driver circuit 200 may provide data voltages to the data lines DL through the fan-out lines FOL. The data voltages may be applied to the plurality of pixels SP, so that the luminance of the plurality of pixels SP may be determined. The display driver circuit 200 may supply a gate control signal to the gate driver 210 through the gate control lines GCL.

In an embodiment, the display pad area DPA, the first touch pad area TPA1 and the second touch pad area TPA2 may be disposed on the edge of the subsidiary area SBA. For example, in an embodiment the display pad area DPA, the first touch pad area TPA1 and the second touch pad area TPA2 may be disposed on a lower edge of the subsidiary area SBA in the y-axis direction. In an embodiment, the display pad area DPA, the first touch pad area TPA1 and the second touch pad area TPA2 may be electrically connected to the display circuit board 300 using a low-resistance, high-reliability material such as an anisotropic conductive layer and a SAP.

The display pad area DPA may include a plurality of display pads. The plurality of display pads may be connected to the display driver circuit 200 through the display circuit board 300. The plurality of display pads may be connected to the display circuit board 300 to receive digital video data and may provide digital video data to the display driver circuit 200.

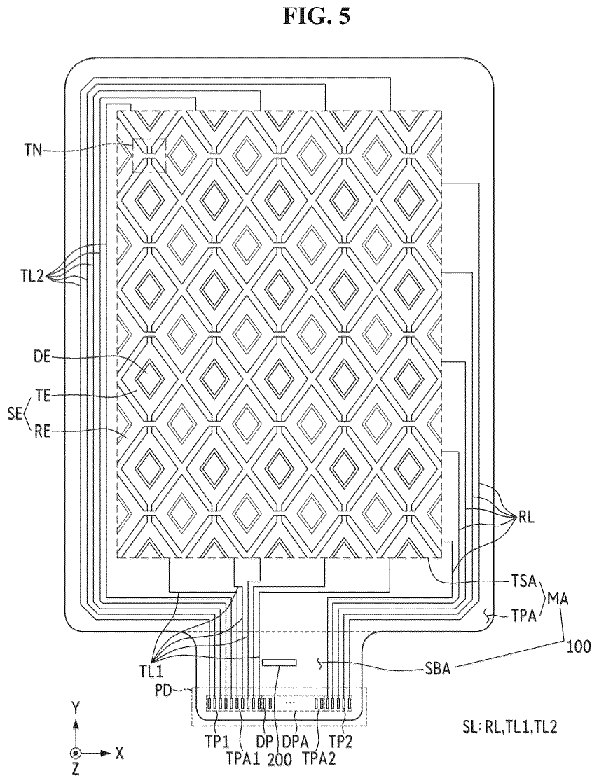

FIG. 5 is a view showing an example of a layout of the touch sensing module shown in FIG. 3.

For convenience of illustration, FIG. 5 shows only the driving electrodes TE, the sensing electrodes RE, dummy patterns DE, touch lines SL, and first and second touch pads TP1 and TP2.

In an embodiment shown in FIG. 5, the touch electrodes SE of the main area MA include two kinds of electrodes, such as the driving electrodes TE and the sensing electrodes RE. The mutual capacitive sensing is carried out by applying touch driving signals to the driving electrode TE, and then sensing the amount of change in the mutual capacitance of each of the touch nodes through the sensing electrodes RE. However, embodiments of the present disclosure are not necessarily limited thereto.

The main area MA of the touch sensing unit TSU includes a touch sensing area TSA for sensing a user's touch, and a touch peripheral area TPA disposed around the touch sensing area TSA (e.g., in a plan view). In an embodiment, the touch sensing area TSA may overlap the display area DA of FIGS. 1 to 3 (e.g., in the z-axis direction), and the touch peripheral area TPA may overlap the non-display area NDA (e.g., in the z-axis direction).

In an embodiment, the driving electrodes TE, the sensing electrodes RE and the dummy patterns DE are disposed in the touch sensing area TSA. The driving electrodes TE and the sensing electrodes RE may be electrodes for forming mutual capacitance to sense a touch of an object or a person.

In an embodiment, the sensing electrodes RE may be arranged in the first direction (e.g., the x-axis direction) and second direction (e.g., the y-axis direction). For example, the sensing electrodes RE may be electrically connected to one another in the first direction (e.g., the x-axis direction). The sensing electrodes RE may be connected to one another in the first direction (x-axis direction). The sensing electrodes RE adjacent to one another in the second direction (e.g., the y-axis direction) may be electrically separated from one another. Accordingly, touch nodes TN where mutual capacitance is formed may be disposed at intersections of the driving electrodes TE and the sensing electrodes RE. A plurality of touch nodes TN may be associated with the intersections of the driving electrodes TE and the sensing electrodes RE, respectively.

The driving electrodes TE may be arranged in the first direction (e.g., the x-axis direction) and the second direction (e.g., the y-axis direction). The driving electrodes TE adjacent to one another in the first direction (e.g., the x-axis direction) may be electrically separated from one another. The driving electrodes TE may be electrically connected to one another in the second direction (e.g., the y-axis direction). The driving electrodes TE adjacent to one another in the second direction (e.g., the y-axis direction) may be connected through separated connection electrodes.

In an embodiment, each of the dummy patterns DE may be surrounded by the driving electrode TE or the sensing electrode RE (e.g., in a plan view). Each of the dummy patterns DE may be electrically separated from the driving electrode TE or the sensing electrode RE. Each of the dummy patterns DE may be spaced apart from the driving electrode TE or the sensing electrode RE. Each of the dummy patterns DE may be electrically floating.

In FIG. 5, the driving electrodes TE, the sensing electrodes RE and the dummy patterns DE each have a diamond shape when viewed from the top (e.g., in a plan view). However, embodiments of the present disclosure are not necessarily limited thereto. For example, in an embodiment each of the driving electrodes TE, the sensing electrodes RE and the dummy patterns DE may have other quadrangular shape than a diamond, other polygonal shapes than a quadrangular shape, a circle or an ellipse when viewed from the top (e.g., in a plan view).

The touch lines SL may be disposed in the sensor peripheral area TPA. In an embodiment, the touch lines SL include first touch driving lines TL1 and second touch driving lines TL2 connected to the driving electrodes TE, and touch sensing lines RL connected to the sensing electrodes RE.

The sensing electrodes RE disposed on one end of the touch sensing area TSA be connected to the touch sensing lines RL, respectively. For example, in an embodiment some of the sensing electrodes RE electrically connected with one another in the first direction (e.g., the x-axis direction) that are disposed at the right end may be connected to the sensing lines RL, respectively, as shown in FIG. 5. The touch sensing lines RL may be connected to second touch pads TP2 disposed on a pad area PD, respectively.

The driving electrodes TE disposed at one end of the touch sensor area TSA may be connected to the first driving lines TL1, respectively, while the driving electrodes TE disposed at the opposite end of the touch sensor area TSA may be connected to the second driving lines TL2, respectively. For example, in an embodiment some of the driving electrodes TE electrically connected to one another in the second direction (e.g., the y-axis direction) that are disposed at the lower end may be connected to the first touch driving lines TL1, respectively, while some of the driving electrodes TE disposed at the upper end may be connected to the second touch driving lines TL2, respectively. The second touch driving lines TL2 may extend around the left side of the touch sensing area TSA and be connected to the driving electrodes TE on the upper side of the touch sensing area TSA (e.g., in the y-axis direction).

In an embodiment, the first touch driving lines TL1 and the second touch driving lines TL2 may be connected to first touch pads TP1 disposed in the pad area PD, respectively. The driving electrodes TE are connected to the first and second touch driving lines TL1 and TL2 on the two sides of the touch sensing area TSA (e.g., in the y-axis direction) to receive touch driving signals. Accordingly, it is possible to prevent a difference between the touch driving signals applied to the driving electrodes TE disposed on the lower side of touch sensing area TSA (e.g., in the y-axis direction) and the touch driving signals applied to the driving electrodes TE disposed on the upper side of the touch sensing area TSA (e.g., in the y-axis direction) due to a RC delay of the touch driving signals.

When the display circuit board 300 is connected to the subsidiary area SBA of the display panel 100, the display pad area DPA and the first and second touch pad areas TPA1 and TPA2 of the pad area PD may be associated with pads of the display panel 100 connected to the display circuit board 300. Accordingly, the pads of the display panel 100 may be in direct contact with the display pads DP, the first touch pads TP1 and the second touch pads TP2. In an embodiment, the display pads DP, the first touch pads TP1 and the second touch pads TP2 may be electrically connected to the pads of the display circuit board 300 using a low-resistance, high-reliability material such as an anisotropic conductive layer and a SAP. Therefore, the display pads DP, the first touch pads TP1 and the second touch pads TP2 may be electrically connected to the touch driver circuit 400 disposed on the display circuit board 300.

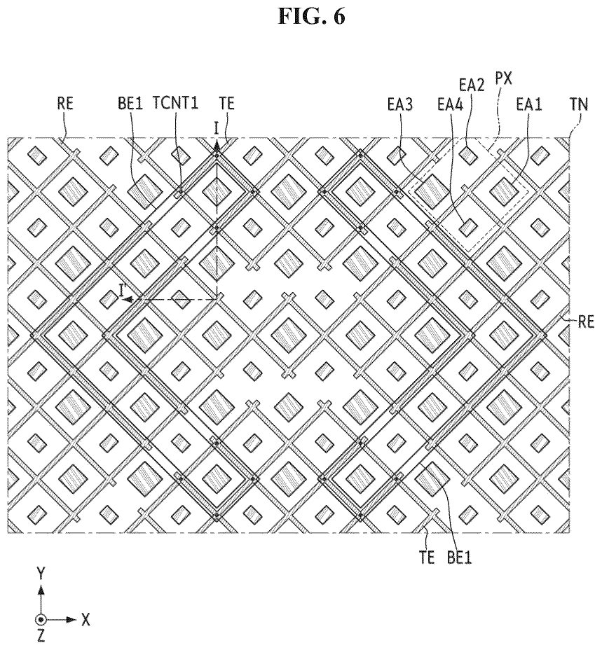

FIG. 6 is an enlarged, plan view showing in detail an example of the touch nodes shown in FIG. 5.

Referring to FIG. 6, the touch nodes TN may be defined as the intersections of the driving electrodes TE and the sensing electrodes RE. In an embodiment, the driving electrodes TE and the sensing electrodes RE are disposed on the same layer and thus they may be spaced apart from each other. For example, there may be a gap between adjacent ones of the driving electrodes TE and the sensing electrodes RE.

In addition, the dummy patterns DE may also be disposed on the same layer as the driving electrodes TE and the sensing electrodes RE. For example, there may be a gap between adjacent ones of the driving electrodes TE and the dummy patterns DE and between adjacent ones of the sensing electrodes RE and the dummy patterns DE.

In an embodiment, the bridge electrodes BE1 may be disposed on a different layer from the driving electrodes TE and the sensing electrodes RE. Each of the bridge electrodes BE1 may be bent at least once.

Although the bridge electrodes BE1 have the shape of angle brackets “<” or “>” in the example shown in FIG. 6, the shape of the bridge electrodes BE1 when viewed from the top (e.g., in a plan view) is not necessarily limited thereto. Since the driving electrodes TE adjacent to each other in the second direction (e.g., the y-axis direction) are connected by the plurality of bridge electrodes BE1, even if any of the bridge electrodes BE1 is disconnected, the driving electrodes TE can still be stably connected with each other. Although two adjacent ones of the driving electrodes TE are connected by two bridge electrodes BE1 in the example shown in FIG. 6, the number of bridge electrodes BE1 is not necessarily limited to two. For example, the number of bridge electrodes BE1 connecting adjacent driving electrodes TE may be three or more in some embodiments.

In an embodiment, the bridge electrodes BE1 may overlap the driving electrodes TE adjacent to one another in the second direction (e.g., the y-axis direction) in the third direction (e.g., the z-axis direction), which is the thickness direction of the substrate SUB. The bridge electrodes BE1 may overlap the sensing electrodes RE in the third direction (e.g., the z-axis direction). In an embodiment, one side (e.g., a first side) of each of the bridge electrodes BE1 may be connected to one of the driving electrodes TE adjacent to each other in the second direction (e.g., the y-axis direction) through touch contact holes TCNT1. The other side (e.g., a second side) of each of the bridge electrodes BE1 may be connected to another one of the driving electrodes TE adjacent to each other in the second direction (e.g., the y-axis direction) through touch contact holes TCNT1.

In an embodiment, the driving electrodes TE and the sensing electrodes RE may be electrically separated from each other at their intersections by virtue of the bridge electrodes BE1. Accordingly, mutual capacitance can be formed between the driving electrodes TE and the sensing electrodes RE.

In an embodiment, each of the driving electrodes TE, the sensing electrodes RE and the bridge electrodes BE1 may have a mesh structure or a net structure when viewed from the top (e.g., in a plan view). In addition, each of the dummy patterns DE may have a shape of a mesh structure or a net structure when viewed from the top (e.g., in a plan view). Accordingly, the driving electrodes TE, the sensing electrodes RE, the bridge electrodes BE1 and the dummy patterns DE may not overlap with the emission areas EA1, EA2, EA3 and EA4 of each of the pixels PX. Therefore, it is possible to prevent the luminance of the lights emitted from the emission areas EA1, EA2, EA3 and EA4 from being lowered, which may occur as the lights are covered by the driving electrodes TE, the sensing electrodes RE, the bridge electrodes BE1 and the dummy patterns DE.

In an embodiment, among the pixels SP in the display area DA, every three or four pixels SP may be defined as a single unit pixel PX capable of producing white light. For example, in an embodiment a first pixel included in a unit pixel PX may include a first emission area EA1 that emits light of a first color, and a second pixel may include a second emission area EA2 that emits light of a second color. A third pixel may include a third emission area EA3 that emits light of a third color, and the fourth pixel may include a fourth emission area EA4 that emits light of the second color or white light. In this embodiment, each unit pixel PX may include the first emission area EA1, the second emission area EA2, the third emission area EA3 and the fourth emission area EA4. In an embodiment, the first color may be red, the second color may be green, the third color may be blue, and the fourth color may be white.

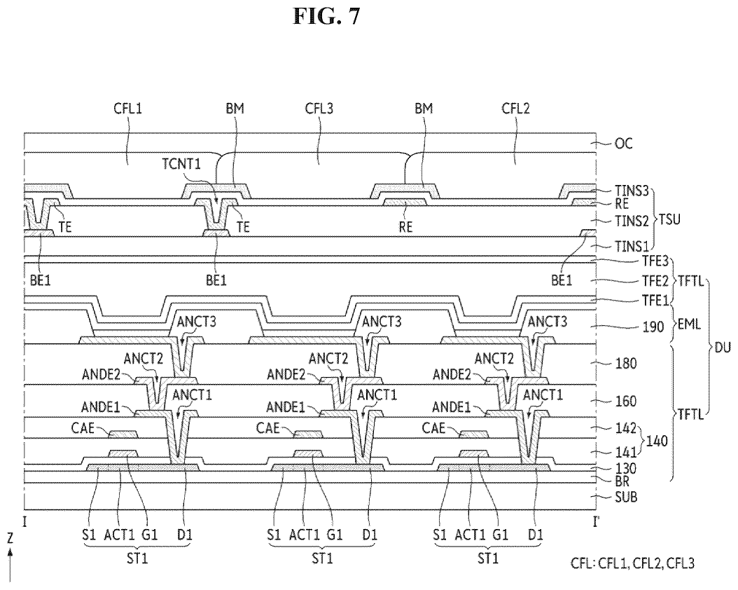

FIG. 7 is a cross-sectional view showing an example of the display panel taken along line I-I′ of FIG. 5.

Referring to FIG. 7, a barrier layer BR may be disposed on the substrate SUB (e.g., disposed directly thereon in the z-axis direction). In an embodiment, the substrate SUB may be made of an insulating material such as a polymer resin. For example, the substrate SUB may be made of polyimide. The substrate SUB may be a flexible substrate that can be bent, folded, or rolled.

The barrier layer BR is a film for protecting the thin-film transistors of the thin-film transistor layer TFTL and an emissive layer 172 of the emission material layer EML. The barrier layer BR may be composed of multiple inorganic layers stacked on one another alternately (e.g., in the z-axis direction). For example, in an embodiment the barrier layer BR may be composed of multiple layers in which one or more inorganic layers of a silicon nitride layer, a silicon oxynitride layer, a silicon oxide layer, a titanium oxide layer and an aluminum oxide layer are alternately stacked on one another (e.g., in the z-axis direction).

Thin-film transistors ST1 may be disposed on the barrier layer BR. Each of the thin-film transistors ST1 includes an active layer ACT1, a gate electrode G1, a source electrode S1, and a drain electrode D1.

The active layer ACT1, the source electrode S1 and the drain electrode D1 of each of the thin-film transistors ST1 may be disposed on the barrier layer BR (e.g., disposed directly thereon in the z-axis direction). In an embodiment, the active layer ACT1 of each of the thin-film transistors ST1 includes polycrystalline silicon, single crystalline silicon, low-temperature polycrystalline silicon, amorphous silicon, or an oxide semiconductor. A portion of the active layer ACT1 overlapping the gate electrode G1 in the third direction (e.g., the z-axis direction) that is the thickness direction of the substrate SUB may be defined as a channel region. The source electrode S1 and the drain electrode D1 are regions that do not overlap with the gate electrode G1 in the third direction (e.g., the z-axis direction), and may have conductivity by doping ions or impurities into a silicon semiconductor or an oxide semiconductor.

A gate insulator 130 may be disposed on the active layer ACT1, the source electrode S1 and the drain electrode D1 of each of the thin-film transistors ST1 (e.g., disposed directly thereon in the z-axis direction). In an embodiment, the gate insulator 130 may be formed of an inorganic layer, for example, a silicon nitride layer, a silicon oxynitride layer, a silicon oxide layer, a titanium oxide layer, or an aluminum oxide layer.

The gate electrode G1 of each of the thin-film transistors ST1 may be disposed on the gate insulator 130 (e.g., disposed directly thereon in the z-axis direction). The gate electrode G1 may overlap the active layer ACT1 in the third direction (e.g., the z-axis direction). In an embodiment, the gate electrode G1 may be composed of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first interlayer dielectric layer 141 may be disposed on (e.g., disposed directly thereon) the gate electrode G1 of each of the thin-film transistors ST1. In an embodiment, the first interlayer dielectric layer 141 may be formed of an inorganic layer, for example, a silicon nitride layer, a silicon oxynitride layer, a silicon oxide layer, a titanium oxide layer, or an aluminum oxide layer. The first interlayer dielectric layer 141 may be made of a plurality of inorganic layers.

A capacitor electrode CAE may be disposed on the first interlayer dielectric layer 141 (e.g., disposed directly thereon in the z-axis direction). The capacitor electrode CAE may overlap the gate electrode G1 of the first thin-film transistor ST1 in the third direction (e.g., the z-axis direction). Since the first interlayer dielectric layer 141 has a predetermined dielectric constant, a capacitor can be formed by the capacitor electrode CAE, the gate electrode G1, and the first interlayer dielectric layer 141 disposed between them. In an embodiment, the capacitor electrode CAE may be composed of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be disposed over the capacitor electrode CAE. In an embodiment, the second interlayer dielectric layer 142 may be formed of an inorganic layer, for example, a silicon nitride layer, a silicon oxynitride layer, a silicon oxide layer, a titanium oxide layer, or an aluminum oxide layer. The second interlayer dielectric layer 142 may be made of a plurality of inorganic layers.

A first anode connection electrode ANDE1 may be disposed on the second interlayer dielectric layer 142 (e.g., disposed directly thereon in the z-axis direction). In an embodiment, the first anode connection electrode ANDE1 may be connected to the drain electrode D1 of the thin-film transistor ST1 through a first connection contact hole ANCT1 that penetrates the gate insulator 130, the first interlayer dielectric layer 141 and the second interlayer dielectric layer 142. In an embodiment, the first anode connection electrode ANDE1 may be composed of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first planarization layer 160 may be disposed over the first anode connection electrode ANDE1 for providing a flat surface over level differences due to the thin-film transistor ST1. In an embodiment, the first planarization layer 160 may be formed of an organic layer such as an acryl resin, an epoxy resin, a phenolic resin, a polyamide resin and a polyimide resin.

A second anode connection electrode ANDE2 may be disposed on the first planarization layer 160 (e.g., disposed directly thereon in the z-axis direction). In an embodiment, the second anode connection electrode ANDE2 may be connected to the first anode connection electrode ANDE1 through a second connection contact hole ANCT2 penetrating the first planarization layer 160. In an embodiment, the second anode connection electrode ANDE2 may be composed of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second planarization layer 180 may be disposed on (e.g., disposed directly thereon) the second anode connection electrode ANDE2. In an embodiment, the second planarization layer 180 may be formed as an organic layer such as an acryl resin, an epoxy resin, a phenolic resin, a polyamide resin and a polyimide resin.

Light-emitting elements LEL and a bank 190 may be disposed on the second planarization layer 180. In an embodiment, each of the light-emitting elements LEL includes a pixel electrode 171, an emissive layer 172, and a common electrode 173.

In an embodiment, the pixel electrode 171 may be disposed on the second planarization layer 180 (e.g., disposed directly thereon in the z-axis direction). In an embodiment, the pixel electrode 171 may be connected to the second anode connection electrode ANDE2 through a third connection contact hole ANCT3 penetrating the second planarization layer 180.

In an embodiment including the top-emission structure in which light exits from the emissive layer 172 towards the common electrode 173, the pixel electrode 171 may be made of a metal material having a high reflectivity such as a stack structure of aluminum and titanium (Ti/Al/Ti), a stack structure of aluminum and indium tin oxide (ITO) (ITO/Al/ITO), an APC alloy and a stack structure of APC alloy and ITO (ITO/APC/ITO). The APC alloy is an alloy of silver (Ag), palladium (Pd) and copper (Cu).

To define the first emission area EA1, the second emission area EA2, the third emission area EA3 and the fourth emission area EA4 in FIG. 5, the bank 190 may be formed to partition the pixel electrode 171 on the second planarization layer 180. For example, the bank 190 may be disposed to cover the edges of the pixel electrode 171 and expose a central portion of the pixel electrode 171. In an embodiment, the bank 190 may be formed of an organic layer such as an acryl resin, an epoxy resin, a phenolic resin, a polyamide resin and a polyimide resin.

In each of the first emission area EA1, the second emission area EA2, the third emission area EA3 and the fourth emission area EA4, the pixel electrode 171, the emissive layer 172 and the common electrode 173 are stacked on one another sequentially (e.g., in the z-axis direction), so that holes from the pixel electrode 171 and electrons from the common electrode 173 are combined with each other in the emissive layer 172 to emit light.

The emissive layer 172 may be disposed on the pixel electrode 171 and the bank 190. The emissive layer 172 may include an organic material to emit light of a certain color. For example, in an embodiment the emissive layer 172 may include a hole transporting layer, an organic material layer, and an electron transporting layer.

The common electrode 173 may be disposed on the emissive layer 172. The common electrode 173 may be disposed to cover the emissive layer 172. In an embodiment, the common electrode 173 may be a common layer formed commonly in the first emission area EA1, the second emission area EA2, the third emission area EA3 and the fourth emission area EA4. In an embodiment, a capping layer may be formed on the common electrode 173 (e.g., formed directly thereon in the z-axis direction).

In the top-emission organic light-emitting diode, the common electrode 173 may be formed of a transparent conductive material (TCP) such as ITO and IZO that can transmit light, or a semi-transmissive conductive material such as magnesium (Mg), silver (Ag) and an alloy of magnesium (Mg) and silver (Ag). In an embodiment in which the common electrode 173 is formed of a semi-transmissive metal material, the light extraction efficiency can be increased by using microcavities.

An encapsulation layer TFEL may be disposed on the common electrode 173 (e.g., in the z-axis direction). The encapsulation layer TFEL includes at least one inorganic layer to prevent permeation of oxygen or moisture into the emission material layer EML. In addition, the encapsulation layer TFEL includes at least one organic layer to protect the light-emitting element layer EML from foreign substances such as dust. For example, in an embodiment the encapsulation layer TFEL includes a first inorganic encapsulation layer TFE1, an organic encapsulation layer TFE2 and a second inorganic encapsulation layer TFE3.

The first inorganic encapsulation layer TFE1 may be disposed on the common electrode 173, the organic encapsulation layer TFE2 may be disposed on the first inorganic encapsulation layer TFE1, and the second inorganic encapsulation layer TFE3 may be disposed on the organic encapsulation layer TFE2. In an embodiment, the first inorganic encapsulation layer TFE1 and the second inorganic encapsulation layer TFE3 may be composed of multiple layers in which one or more inorganic layers of a silicon nitride layer, a silicon oxynitride layer, a silicon oxide layer, a titanium oxide layer and an aluminum oxide layer are alternately stacked on one another. In an embodiment, the organic encapsulation layer TFE2 may be an organic layer such as an acryl resin, an epoxy resin, a phenolic resin, a polyamide resin, a polyimide resin, etc.

TABLE 1

| | Refractive | SCI Reflection | | | SCE Reflection | | |
|---|---|---|---|---|---|---|---|
| YCALD | Index | Y | a* | b* | Y | a* | b* |
| SiON 100 nm | 1.70 | 6.27 | 0.18 | −3.00 | 0.58 | 0.17 | −4.10 |
| SION 200 nm | 1.70 | 6.25 | 0.16 | −3.01 | 0.58 | 0.20 | −4.18 |
| SiON 70 nm | 1.70 | 6.26 | 0.18 | −3.00 | 0.58 | 0.17 | −4.22 |
| SiON 1000Å | 1.87 | 6.28 | 0.20 | −2.98 | 0.58 | 0.17 | −4.04 |

Table 1 above shows the refractive index and thickness values of the encapsulation layer TFEL, the refractive index and thickness values of each of the first to third touch insulating layers TINS1, TINS2 and TINS3 formed in the touch sensing unit TSU, the refractive index and thickness values of each of the first to third color filters CFL1, CFL2 and CFL3 included in the color filter layer CFL, and the refractive index and thickness values of at least one cover window OC.

Referring to Table 1, the encapsulation layer TFEL formed to cover the emission material layer EML of the display panel 100 may be composed of an organic layer formed of an organic material, an inorganic layer formed of an inorganic material, or multiple layers of a combination of an organic material and an inorganic material. The encapsulation layer TFEL may have a first thickness (e.g., a first layer thickness) of 440 nm and a first refractive index of approximately 1.87. The encapsulation layer TFEL may include at least one inorganic material selected from the group consisting of silicon nitride, silicon oxynitride, silicon oxide, titanium oxide and aluminum oxide, and at least one organic material selected from the group consisting of acrylic resin, epoxy resin, phenolic resin, polyamide resin and polyimide resin.

The touch sensing unit TSU is formed on the encapsulation layer TFEL (e.g., formed directly thereon in the third direction DR3).

In an embodiment, the touch sensing unit TSU includes a first touch insulating layer TINS1, bridge electrodes BE1, a second touch insulating layer TINS2, the driving electrodes TE, the sensing electrodes RE, and a third touch insulating layer TINS3.

In Table 1, Y-ILD represents a transmissive area of the first touch insulating layer TINS1, Y-CNT represents a transmissive area of the second touch insulating layer TINS2, Y-CLAD represents a transmissive area of the third touch insulating layer TINS3, and YOCTA represents the transmissive areas of the first to third touch insulating layers TINS1, TINS2 and TINS3.

In an embodiment, the first touch insulating layer TINS1 of the touch sensing unit TSU is formed entirely on the touch sensing area TSA and the touch peripheral area TPA.

The first touch insulating layer TINS1 is formed to cover the entire surface of the encapsulation layer TFEL. For example, in an embodiment, the first touch insulating layer TINS1 may be disposed on a front surface of the encapsulation layer TFEL. The first touch insulating layer TINS1 has a second thickness that is less than the first thickness of the encapsulation layer TFEL and has a second refractive index that is greater than the first refractive index of the encapsulation layer TFEL. The first touch insulating layer TINS1 may include at least one inorganic material selected from the group consisting of silicon oxide, titanium oxide, aluminum oxide, and silicon nitride (SiNx). For example, the first touch insulating layer TINS1 may have a second thickness (e.g., a second layer thickness) of 200 nm and have a second refractive index of approximately 1.92.

The bridge electrodes BE1 may be formed and disposed on (e.g., directly thereon in the z-axis direction) the first touch insulating layer TINS1 of the touch sensing area TSA. In an embodiment, the connection electrodes BE1 may be composed of a single layer or multiple layers of one of molybdenum (Mo), aluminum (Al), chromium (Cr), gold (Au), titanium (Ti), nickel (Ni), neodymium (Nd) and copper (Cu) or an alloy thereof.

In an embodiment, during the process of forming the bridge electrodes BE1, the touch sensing lines RL may be formed and disposed in the touch peripheral area TPA with the same metal material and via the same patterning process as the connection electrodes BE1. The touch sensing lines RL may be patterned in a shape with a predetermined spacing and a predetermined length.

In an embodiment, the second touch insulating layer TINS2 is formed entirely on the first touch insulating layer TINS1 so that it covers the bridge electrodes BE1 in the touch sensing area TSA and the touch sensing lines RL in the touch peripheral area TPA. For example, in an embodiment, the second touch insulating layer TINS2 may be disposed on a front surface of the first touch insulating layer TINS1. The second touch insulating layer TINS2 has a third thickness that is greater than the second thickness of the first touch insulating layer TINS1, and has a third refractive index that is less than the second refractive index of the first touch insulating layer TINS1. The second touch insulating layer TINS2 may include at least one inorganic material selected from the group consisting of: silicon nitride, silicon oxide, titanium oxide and aluminum oxide, and at least one organic material selected from the group consisting of acrylic resin, epoxy resin, phenolic resin, polyamide resin and polyimide resin. For example, the second touch insulating layer TINS2 may have a third thickness (e.g., a third layer thickness) of 300 nm and have a third refractive index of approximately 1.87.

The driving electrodes TE, the sensing electrodes RE and the dummy patterns DE may be formed and disposed on (e.g., patterned directly thereon in the z-axis direction) the second touch insulating layer TINS2 of the touch sensing area TSA. In an embodiment, the driving electrodes TE, the sensing electrodes RE and dummy patterns DE may be formed of one of molybdenum (Mo), aluminum (Al), chromium (Cr), gold (Au), titanium (Ti), nickel (Ni), neodymium (Nd) and copper (Cu), or an alloy thereof.

In an embodiment, during the process of forming the driving electrodes TE, the sensing electrodes RE and the dummy patterns DE, first and second touch driving signal lines TL1 and TL2 may be formed and disposed in the touch peripheral area TPA with the same metal material via the same patterning process as the driving electrodes TE, the sensing electrodes RE and the dummy patterns DE. The first and second touch driving signal lines TL1 and TL2 may be patterned in a shape with a predetermined spacing and a predetermined length. The driving electrodes TE formed via the same patterning process may be electrically connected to the first and second touch driving lines TL1 and TL2.

The driving electrodes TE and the sensing electrodes RE may overlap with the bridge electrodes BE1 in the third direction (e.g., the z-axis direction). The driving electrodes TE may be connected to the bridge electrodes BE1 through touch contact holes TCNT1 penetrating through the second touch insulating layer TINS2. The sensing electrodes RE may be electrically connected to the touch sensing lines RL, respectively, through the touch contact holes TCNT1 penetrating the second touch insulating layer TINS2.

The third touch insulating layer TINS3 may be formed on the touch sensing area TSA where the driving electrodes TE, the sensing electrodes RE, and the dummy patterns DE are formed.

In an embodiment, the third touch insulating layer TINS3 is formed on the front surface of the second touch insulating layer TIN2 such that it covers all of the driving electrodes TE and the sensing electrodes RE in the touch sensing area TSA and the dummy patterns DE in the touch peripheral area TPA.

The third touch insulating layer TINS3 has a fourth thickness that is greater than the third thickness of the second touch insulating layer TINS2, and has a fourth refractive index that is less than the third refractive index of the second touch insulating layer TINS2. The third touch insulating layer TINS3 may be formed of silicon oxynitride. For example, the third touch insulating layer TINS3 may have a fourth thickness (e.g., a fourth layer thickness) of about 70 nm and have a fourth refractive index of approximately 1.70.

TABLE 2

| Y-CLAD | | | |
|---|---|---|---|
| | Refractive | Thickness | Reflectance |
| Material | Index | (nm) | SCI YY |
| SiNx | n1.87 | 100 | 6.31 |
| (original) | | | |
| SiON | n1.7 | 100 | 6.29 |
| (¼λ) | | 90 | 6.27 |
| | | 80 | 6.27 |
| | | 70 | 6.27 |
| | | 60 | 6.27 |
| | | 50 | 6.28 |
| SiON | n1.7 | 170 | 6.30 |
| (¾λ) | | 180 | 6.27 |
| | | 190 | 6.27 |
| | | 200 | 6.27 |
| | | 210 | 6.24 |
| | | 220 | 6.24 |
| | | 240 | 6.27 |

Table 2 shows changes in refractive index and reflectance versus the thickness of the third touch insulating layer TINS3 for different optical wavelength interference conditions (¼ λ and ¾ λ) depending on silicon oxynitride (SiON).

The third touch insulating layer TINS3 formed of silicon oxynitride (SiON) has a fourth refractive index of approximately 1.70 due the thickness (d) of the third touch insulating layer TINS3 which may be derived using Equation 1 and Equation 2 below:

$${n}_{YCLAD} = \sqrt{{n}_{YCNT} \cdot {n}_{CF}} = 1.7 \qquad [ Equation 1 ]$$

$$d = ( \frac{1}{4} ) \frac{λ}{{n}_{YCLAD}} = 70 nm \qquad [ Equation 2 ]$$

where nYCLAD denotes the refractive index of the third touch insulating layer TINS3, and nYCNT denotes the refractive index of the second touch insulating layer TINS2. In addition, nCF denotes the refractive index of one of the first to third color filters CFL1, CFL2 and CFL3.

Referring to the calculation results according to Equation 1 and Equation 2 and Table 2 above, the third touch insulating layer TINS3 formed of silicon oxynitride (SiON) has the fourth thickness (e.g., a fourth layer thickness) of about 70 nm or about 210 nm, and thus may have the fourth refractive index of approximately 1.70.

A plurality of light-blocking patterns BM is formed on (e.g., formed directly thereon) the third touch insulating layer TINS3 in the touch sensing area TSA so that they are in line with non-image display portions between the pixels ST. The plurality of light-blocking patterns BM may be formed in a mesh pattern when viewed from the top conforming to the shape of the non-image display portions. The plurality of light-blocking patterns BM may be formed of materials including infrared or ultraviolet ray absorbing material. For example, in an embodiment the plurality of light-blocking patterns BM may include an inorganic black pigment containing at least one compound of carbon black, cyanine, polymethine, anthraquinone, and a phthalocyanine compound. In addition, the plurality of light-blocking patterns BM may include at least one organic black pigment selected from lactam black, perylene black, and aniline black.

On the third touch insulating layer TINS3 in the touch sensing area TSA corresponding to the image display area DA, a color filter layer CFL is formed to cover the pixels ST as well as the plurality of light-blocking patterns BM.

In an embodiment, the color filter layer CFL includes a plurality of first to third color filters CFL1, CFL2 and CFL3. The plurality of first to third color filters CFL1, CFL2 and CFL3 may be disposed over the plurality of light-blocking patterns BM and the third touch insulating layer TINS3. For example, the color filter layer CFL may be formed on the third touch insulating layer TINS3 such that it overlaps with the first to fourth emission areas EA1 to EA4 (e.g., in the z-axis direction).

Referring to Table 1, among the refractive indices of the color filter layer CFL, RD 1.61 is the refractive index for the red first color filter CFL1, and GR 1.54 is the refractive index for the green second color filter CFL2. In addition, among the refractive indices of the color filter layer CFL, BL 1.47 is the refractive index for the blue third color filter CFL3. The thickness of each of the first to third color filters CFL1, CFL2 and CFL3 may be approximately 3,000 nm.

The color filters CFL1, CFL2 and CFL3 may have a fifth thickness that is greater than the fourth thickness of the third touch insulating layer TINS3 and may have a fifth refractive index that is less than the fourth refractive index of the third touch insulating layer TINS3. For example, the color filters CFL1, CFL2 and CFL3 may have the fifth thickness (e.g., fifth layer thickness) of 3,000 nm and may have the fifth refractive index of approximately 1.47 to 1.61.

In an embodiment, at least one cover window OC may be disposed entirely on the display panel 100 including the color filters CFL1, CFL2 and CFL3. For example, the cover window OC may be attached entirely to the display panel 100 using a transparent adhesive member such as an optically clear adhesive (OCA) layer and an optically clear resin (OCR).

At least one cover window OC has a sixth thickness that is less than the fifth thickness of the color filters CFL1, CFL2 and CFL3 and is greater than the fourth thickness of the third touch insulating layer TINS3, and has a sixth refractive index that is less than the fifth refractive index of the color filters CFL1, CFL2 and CFL3. The cover window CW may be made of either an inorganic material such as glass or an organic material such as plastic and polymer material.

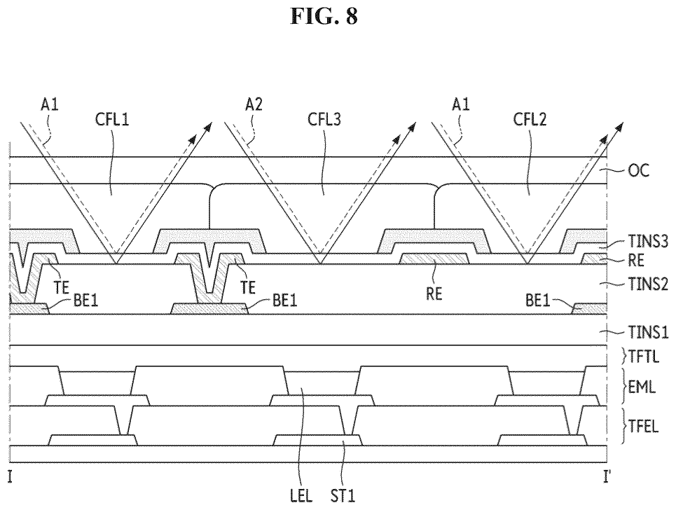

FIG. 8 is a cross-sectional view showing the cross-sectional structure taken along line I-I′ of FIG. 7 as simple blocks.

Referring to FIGS. 7 and 8, the third touch insulating layer TINS3 of the touch sensing unit TSU has a fourth thickness that is less than the second thickness of the first touch insulating layer TINS1, and accordingly has a fourth refractive index that is less than the second refractive index of the first touch insulating layer TINS1. In addition, the third touch insulating layer TINS3 has the fourth thickness that is less than the third thickness of the second touch insulating layer TINS2, and has the fourth refractive index that is less than the third refractive index of the second touch insulating layer TINS2. Alternatively, the third touch insulating layer TINS3 has the fourth thickness that is less than the fifth thickness of the color filters CFL1, CFL2 and CFL3 and accordingly has the fourth refractive index greater than the fifth refractive index of the color filters CFL1, CFL2 and CFL3.

For example, in an embodiment the third touch insulating layer TINS3 has the fourth thickness that is less than the third thickness of the second touch insulating layer TINS2 and the fifth thickness of the color filters CFL1, CFL2 and CFL3, and has the fourth refractive index that is less than the third refractive index of the second touch insulating layer TINS2 and greater than the fifth refractive index of the color filters CFL1, CFL2 and CFL3.

For example, in an embodiment the third touch insulating layer TINS3 is formed to have a thickness that is less than the thicknesses of the second touch insulating layer TINS2 and the color filters CFL1, CFL2 and CFL3, and has the fourth refractive index ranging between the third refractive index of the second touch insulating layer TINS2 and the fifth refractive index of the color filters CFL1, CFL2 and CFL3.

In an embodiment, the second touch insulating layer TINS2 has the third thickness that is greater than the second thickness of the first touch insulating layer TINS1 formed on the rear surface, and has the third refractive index that is less than the second refractive index of the first touch insulating layer TINS1.

As indicated by a first arrow A1 and a second arrow A2, lights pass through the color filters CFL1, CFL2 and CFL3 having the fifth refractive index that is less than the third and fourth refractive indices of the second and third touch insulating layers TINS2 and TINS3, and then are reflected by the second and third touch insulating layers TINS2 and TINS3. In an embodiment, after having passes through the color filters CFL1, CFL2 and CFL3, the lights are reflected by the thickest second touch insulating layer TINS2 rather than the thinnest third insulating layer TIN3 having the lowest refractive index among the first to third touch insulating layers TINS1, TINS2 and TINS3. As described above, the third touch insulating layer TINS3 is the thinnest and has the fourth refractive index that is less than the third refractive index of the second touch insulating layer TINS2 and greater than the fifth refractive index of the color filters CFL1, CFL2 and CFL3, and thus destructive interference between lights reflected by the third touch insulating layer TINS3 and the second touch insulating layer TINS2 can increase.

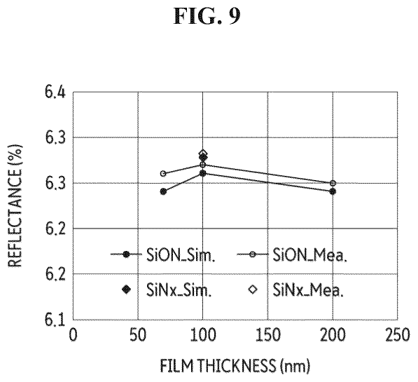

FIG. 9 is a graph showing the effects of reducing light reflectance by enhancing the materials and layer thicknesses of the touch insulating layers. Table 3 shows the amount of reflected light versus the refractive index of silicon nitride (SiNx) and silicon oxynitride (SiON) for different thicknesses.

TABLE 3

| | | Existing Structure | | Improved Structure | |
|---|---|---|---|---|---|
| | | Refrac- | Thick- | Refrac- | Thick- |
| | | tive | ness | tive | ness |
| | Layer | Index | (nm) | Index | (nm) |
| Color Filter, | OC | 1.55 | 1500 | 1.55 | 1500 |
| OC | CF | RD 1.61 | 3000 | RD 1.61 | 3000 |
| | | GR 1.54 | 3000 | GR 1.54 | 3000 |
| | | BL 1.47 | 3000 | BL 1.47 | 3000 |
| YOCTA | Y-CLAD | 1.87 | 100 | 1.70 | 70 |
| (Transmissive | Y-CNT | 1.87 | 300 | 1.87 | 300 |
| Area) | Y-ILD | 1.92 | 200 | 1.92 | 200 |
| TFEL | TFEL | 1.87 | 440 | 1.87 | 440 |

Referring to FIG. 9 and Table 3, we can see the effects of reducing the amounts of specular component included (SCI) reflection and the amounts of specular component excluded (SCE) reflection, as well as the refractive indexes silicon oxynitride (SiON) with the fourth thickness.

In an embodiment, as shown in FIG. 9, the reflectance can be more effectively reduced by using silicon oxy nitride (SiON) rather than silicon nitride (SiNx).

In view of the above, in the display device 10 according to embodiments of the present disclosure, it is possible to prevent distortion of the reflectance in the front direction due to differences in the refractive indexes of the color filters CFL1, CFL2 and CFL3, thereby preventing deterioration of the display quality and increasing user satisfaction. In addition, the light reflectance of the touch insulating layers TINS1, TINS2 and TINS3 can be reduced by enhancing the refractive indexes of the touch insulating layers TINS1, TINS2 and TINS3 to increase the display quality and increase user reliability.

The display device according to the embodiment can be applied to various electronic devices. The electronic device according to one embodiment includes the display device described above and may further include modules or devices having additional functions in addition to the display device.

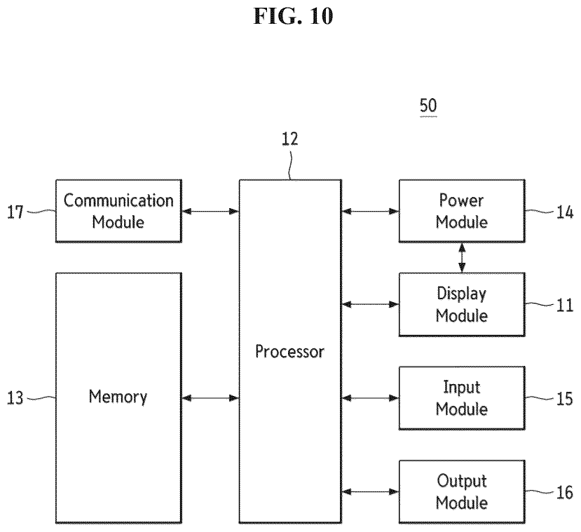

FIG. 10 is a block diagram of an electronic device according to one embodiment. Referring to FIG. 10, the electronic device 50 according to one embodiment may include a display module 11, a processor 12, a memory 13, and a power module 14. The electronic device 5000 may further include an input module 15, a non-image output module 16 and/or a communication module 17.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 15 may provide input information to the processor 12 and/or the display module 11. The non-image output module 16 may receive information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 50 other than the display device.

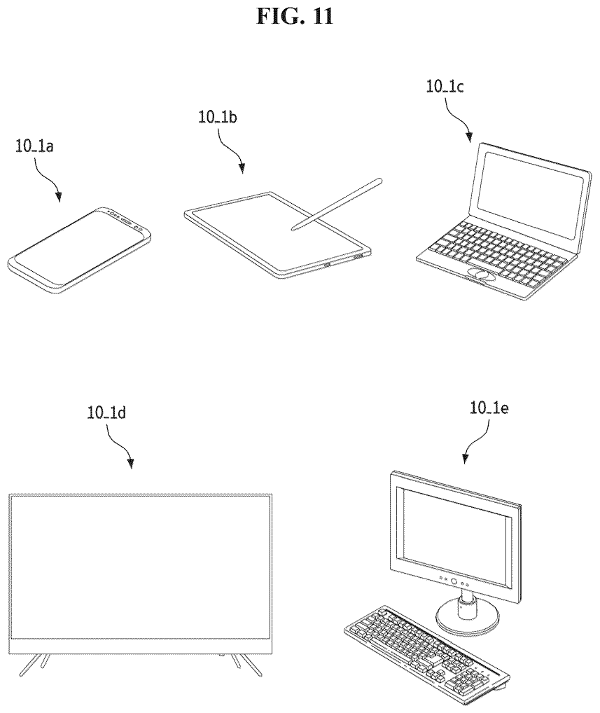

FIGS. 11, 12, and 13 are schematic diagrams of electronic devices according to various embodiments. FIGS. 11 to 13 illustrate examples of various electronic devices to which the display device according to the embodiments is applied.

FIG. 11 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

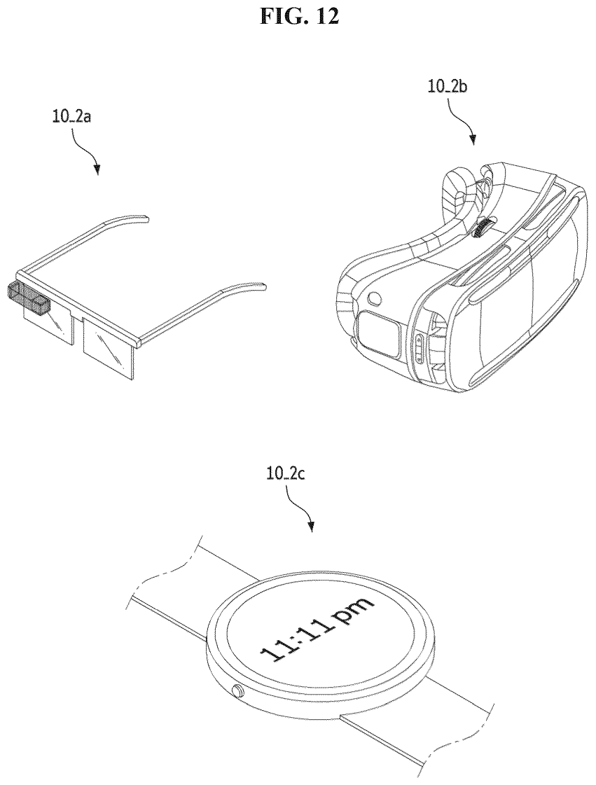

FIG. 12 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

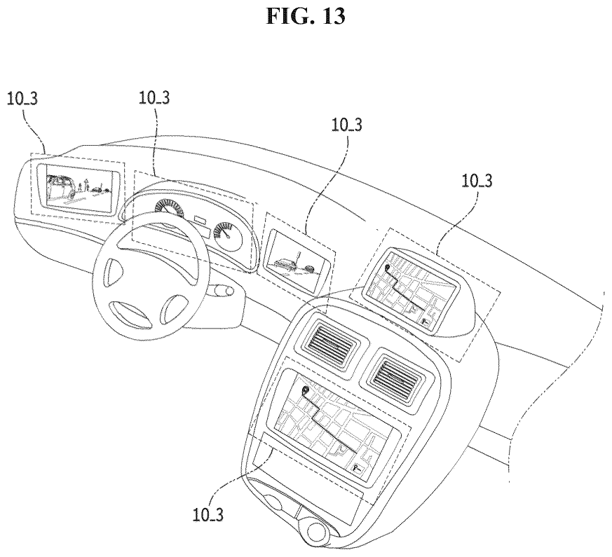

The smart watch 10_2c includes a biometric sensor as an input device, and may provide biometric information recognized by the biometric sensor to the user through the display module. FIG. 13 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the described embodiments without substantially departing from the principles of embodiments of the present disclosure. Therefore, the described embodiments of the present disclosure are used in a generic and descriptive sense only and not for purposes of limitation.

What is claimed is:

1. A display device comprising:
a display panel comprising a display area including a plurality of pixels disposed therein; and
a touch sensing unit disposed on a front surface of the display panel, the touch sensing unit sensing a user's touch,
wherein the touch sensing unit comprises:
a first touch insulating layer disposed on a front surface of an encapsulation layer formed in the display area;
a second touch insulating layer disposed on a front surface of the first touch insulating layer;
a plurality of touch electrodes patterned on the second touch insulating layer;
a third touch insulating layer disposed on the plurality of touch electrodes and a front surface of the second touch insulating layer;
a color filter layer disposed on the third touch insulating layer and overlapping the plurality of pixels in the display area; and
at least one cover window disposed on the color filter layer and the front surface of the display panel, and
wherein the third touch insulating layer is composed of an insulating material having a refractive index ranging between a refractive index of the second touch insulating layer and a refractive index of the color filter layer.

2. The display device of claim 1, wherein the third touch insulating layer is composed of an inorganic insulating material with a thickness less than a thickness of the second touch insulating layer and a thickness of the color filter layer.

3. The display device of claim 2, wherein the third touch insulating layer has a thickness of about 70 nm or about 210 nm and comprises silicon oxynitride (SiON) that is an inorganic insulating material different from materials of the first and second touch insulating layers.

4. The display device of claim 1, wherein:
the encapsulation layer is composed of an organic material layer, an inorganic material layer or multiple layers that is a combination of an organic material layer and an inorganic material layer; and
the encapsulation layer has a predetermined first thickness that provides a predetermined first refractive index.

5. The display device of claim 4, wherein:
the first touch insulating layer has a second thickness that is less than the first thickness of the encapsulation layer and has a second refractive index that is greater than the first refractive index of the encapsulation layer; and
the first touch insulating layer comprises at least one inorganic insulating material selected from silicon oxide, titanium oxide layer, aluminum oxide, and silicon nitride.

6. The display device of claim 5, wherein the second touch insulating layer has a third thickness greater than the second thickness of the first touch insulating layer, has a third refractive index less than the second refractive index of the first touch insulating layer, and
wherein the second touch insulating layer is composed of at least one inorganic material selected from silicon nitride, silicon oxide, titanium oxide and aluminum oxide, and at least one organic material selected from an acrylic resin, an epoxy resin, a phenol resin, a polyamide resin and a polyimide resin.

7. The display device of claim 6, wherein the third touch insulating layer has a fourth thickness that is less than a thickness of the color filter layer and less than the third thickness of the second touch insulating layer, and has a fourth refractive index that is less than the third refractive index of the second touch insulating layer and greater than the refractive index of the color filter layer.

8. The display device of claim 7, wherein the third touch insulating layer has a thickness of about 70 nm or about 210 nm and comprises silicon oxynitride (SiON) that is an inorganic insulating material different from materials of the first and second touch insulating layers.

9. The display device of claim 7, wherein the color filter layer has a fifth thickness that is greater than the fourth thickness of the third touch insulating layer, and has a fifth refractive index that is less than the fourth refractive index of the third touch insulating layer, and
wherein the at least one cover window has a sixth thickness that is less than the fifth thickness of the color filter layer and greater than the fourth thickness of the third touch insulating layer, and has a sixth refractive index that is less than the fifth refractive index of the color filter layer.

10. A display device comprising:
a display panel comprising a display area including a plurality of pixels disposed therein;
an encapsulation layer arranged to cover a front surface of the display area;
a first touch insulating layer disposed on a front surface of the encapsulation layer;
a second touch insulating layer disposed on a front surface of the first touch insulating layer;
a plurality of touch electrodes patterned on the second touch insulating layer;
a third touch insulating layer disposed on the plurality of touch electrodes and a front surface of the second touch insulating layer;
a color filter layer disposed on the third touch insulating layer and overlapping with the plurality of pixels in the display area; and
at least one cover window disposed on the color filter layer and a front surface of the display panel, and
wherein the third touch insulating layer has a refractive index that is less than a refractive index of the second touch insulating layer and greater than a refractive index of the color filter layer.

11. The display device of claim 10, wherein:
the third touch insulating layer has a thickness of about 70 nm or about 210 nm;
the thickness of the third touch insulating layer is less than thicknesses of the second touch insulating layer and the color filter layer; and
the third touch insulating layer comprises silicon oxynitride (SiON), that is an inorganic insulating material different from materials of the first and second touch insulating layers.

12. The display device of claim 10, wherein:
the encapsulation layer is composed of an organic material layer, an inorganic material layer or multiple layers that is a combination of an organic material layer and an inorganic material layer; and
the encapsulation layer has a predetermined first thickness that provides a predetermined first refractive index.

13. The display device of claim 12, wherein:
the first touch insulating layer has a second thickness that is less than the first thickness of the encapsulation layer and has a second refractive index that is greater than the first refractive index of the encapsulation layer; and
the first touch insulating layer comprises at least one inorganic insulating material selected from silicon oxide, titanium oxide layer, aluminum oxide, and silicon nitride.

14. The display device of claim 13, wherein the second touch insulating layer has a third thickness greater than the second thickness of the first touch insulating layer, has a third refractive index less than the second refractive index of the first touch insulating layer, and
wherein the second touch insulating layer is formed of at least one inorganic material selected from silicon nitride, silicon oxide, titanium oxide and aluminum oxide, and at least one organic material selected from an acrylic resin, an epoxy resin, a phenol resin, a polyamide resin and a polyimide resin.

15. The display device of claim 14, wherein the third touch insulating layer has a fourth thickness that is less than a thickness of the color filter layer and less than the third thickness of the second touch insulating layer, and has a fourth refractive index that is less than the third refractive index of the second touch insulating layer and greater than the refractive index of the color filter layer.

16. The display device of claim 15, wherein the color filter layer has a fifth thickness that is greater than the fourth thickness of the third touch insulating layer, and has a fifth refractive index that is less than the fourth refractive index of the third touch insulating layer, and
wherein the at least one cover window has a sixth thickness that is less than the fifth thickness of the color filter layer and greater than the fourth thickness of the third touch insulating layer, and has a sixth refractive index that is less than the fifth refractive index of the color filter layer.

17. An electronic device comprising:
a processor;
a memory connected to the processor; and
a display device connected to the processor,
wherein the display device comprising:
a display panel comprising a display area including a plurality of pixels disposed therein; and
a touch sensing unit disposed on a front surface of the display panel, the touch sensing unit sensing a user's touch,
wherein the touch sensing unit comprises:
a first touch insulating layer disposed on a front surface of an encapsulation layer formed in the display area;
a second touch insulating layer disposed on a front surface of the first touch insulating layer;
a plurality of touch electrodes patterned on the second touch insulating layer;
a third touch insulating layer disposed on the plurality of touch electrodes and a front surface of the second touch insulating layer;
a color filter layer disposed on the third touch insulating layer and overlapping the plurality of pixels in the display area; and
at least one cover window disposed on the color filter layer and the front surface of the display panel, and
wherein the third touch insulating layer is composed of an insulating material having a refractive index ranging between a refractive index of the second touch insulating layer and a refractive index of the color filter layer.

18. The electronic device of claim 17, wherein the third touch insulating layer is composed of an inorganic insulating material with a thickness less than a thickness of the second touch insulating layer and a thickness of the color filter layer.

19. The electronic device of claim 18, wherein the third touch insulating layer has a thickness of about 70 nm or about 210 nm and comprises silicon oxynitride (SiON) that is an inorganic insulating material different from materials of the first and second touch insulating layers.

20. The electronic device of claim 17, wherein:
the encapsulation layer is composed of an organic material layer, an inorganic material layer or multiple layers that is a combination of an organic material layer and an inorganic material layer; and
the encapsulation layer has a predetermined first thickness that provides a predetermined first refractive index.
